(19) United States
(12) Patent Application Publication
(10) Pub. No.: US 2012/0243165 A1
(43) Pub. Date: Sep. 27, 2012

(54) DUAL-SCREEN PORTABLE COMPUTER AND A SWITCHING METHOD OF THE SAME

(75) Inventors: Yao-Tsung CHANG, Taipei Hsien (TW); Chia-Hsien Li, Taipei Hsien (TW); Yi-Wei TAU, Taipei Hsien (TW)

(73) Assignee: Wistron Corporation, Taipei Hsien (TW)

(21) Appl. No.: 13/429,734

(22) Filed: Mar. 26, 2012

(30) Foreign Application Priority Data
Mar. 25, 2011 (TW) 100110433

(51) Int. Cl. H05K 7/00

(52) U.S. Cl. 361/679.27

(57) ABSTRACT

A dual-screen computer includes a display module and a body. The display module includes a first screen and a second screen, wherein these two screens are separately disposed on opposite sides of the display module. The body contains a plurality of graphics controllers. Each graphics controller is electrically connected to the first screen and the second screen separately for controlling the first screen and the second screen to display graphics individually.

### BACKGROUND OF THE INVENTION

1. Field of the Invention

The present invention relates to a dual-screen portable computer, especially a dual-screen portable computer in which each screen can display graphics independently.

2. Description of the Related Art

Dual-screen devices such as dual-screen digital cameras, dual-screen mobile phones, and dual-screen laptops are very common. However, the second screen of the dual-screen laptops is generally small, and the second screen has only limited functions or displays specific information, such as the status of the laptop, or simply plays audio/visual files, because of the limitation of the build-in graphics controller of the dual-screen laptop. The ACER® Iconia is a dual-screen laptop whose two screens are located next to each other, and the second screen is disposed in the location where the keyboards of normal laptops are disposed. Therefore, the second screen has to display a virtual keyboard for users to manipulate the dual-screen laptop. The second screen is available for playing audio/visual files only when users do not need the virtual keyboard, resulting in limited usage of the second screen.

As tablet computers become popular, electronic products that combine notebook and tablet computers are released one after another by electronics companies. For instance, the DELL® Inspiron Duo Tablet can be used as a notebook or a tablet computer by rotating the screen 180° or 360° within the upper case. Moreover, the screen of the ACER® Travelmate C310 can be rotated 180°, together with the upper case, in order to switch its usage function. However, in order to switch the notebook function and the tablet computer function successfully, users have to remember the rotating methods and steps for rotating the main screen, for the abovementioned products are equipped with only a single screen.

It is necessary to provide a dual-screen portable computer that can display graphics independently, such that the usage modes can be changed according to user's needs, and such that both of its screens can execute full display functions when the dual-screen portable computer is used in a laptop mode.

### SUMMARY OF THE INVENTION

An object of the present invention is to provide a dual-screen portable computer, each screen of which can display graphics independently.

Another object of the present invention is to provide a dual-screen portable computer that can be operated in a tablet mode and in a notebook mode.

To achieve the aforementioned objects, the present invention of the dual-screen portable computer mainly comprises a display module and a body. The display module includes a first screen and a second screen, wherein the first screen and the second screen are disposed on the opposite sides of the display module separately. The body comprises a plurality of graphics controllers for separately controlling the first screen and the second screen to display graphics, the plurality of graphics controllers being electrically connected to the first screen and the second screen.

In one embodiment of the present invention, the dual-screen portable computer can be operated in an e-reader mode, and one of the screens is an e-paper display module.

In one embodiment of the present invention, the dual-screen portable computer is equipped with a double-hinge device for allowing the first screen to be folded to the top surface of the body or the second screen to be folded to the bottom surface of the body for operation in the tablet mode.

### BRIEF DESCRIPTION OF THE DRAWINGS

FIG. 1 illustrates the hardware structure of the first embodiment of the dual-screen portable computer.

FIG. 2 is a schematic drawing of the dual-screen portable computer in a laptop mode.

FIG. 3 is a schematic drawing of the first embodiment of the dual-screen portable computer in an opened state.

FIG. 4 is another schematic drawing of the first embodiment of the dual-screen portable computer in the opened state.

FIG. 5 is a lateral view of the first embodiment of the dual-screen portable computer in the opened state.

FIG. 6 is a schematic drawing of the first embodiment of the dual-screen portable computer in a folded state.

FIG. 7 is a schematic drawing of the second embodiment of the dual-screen portable computer in the opened state.

FIG. 8 is a schematic drawing of the second embodiment of the dual-screen portable computer showing the movement of changing the state from the opened state to the folded state.

FIG. 9 is a schematic drawing of the third embodiment of the dual-screen portable computer in the folded state.

FIG. 10 is a flow chart of one embodiment of the switching method of a portable computer of the present invention.

FIG. 11 is a flow chart of another embodiment of the switching method of the portable computer of the present invention.

### DETAILED DESCRIPTION OF THE PREFERRED EMBODIMENT

The advantages and innovative features of the invention will become more apparent from the following detailed descriptions when taken together with the accompanying drawings.

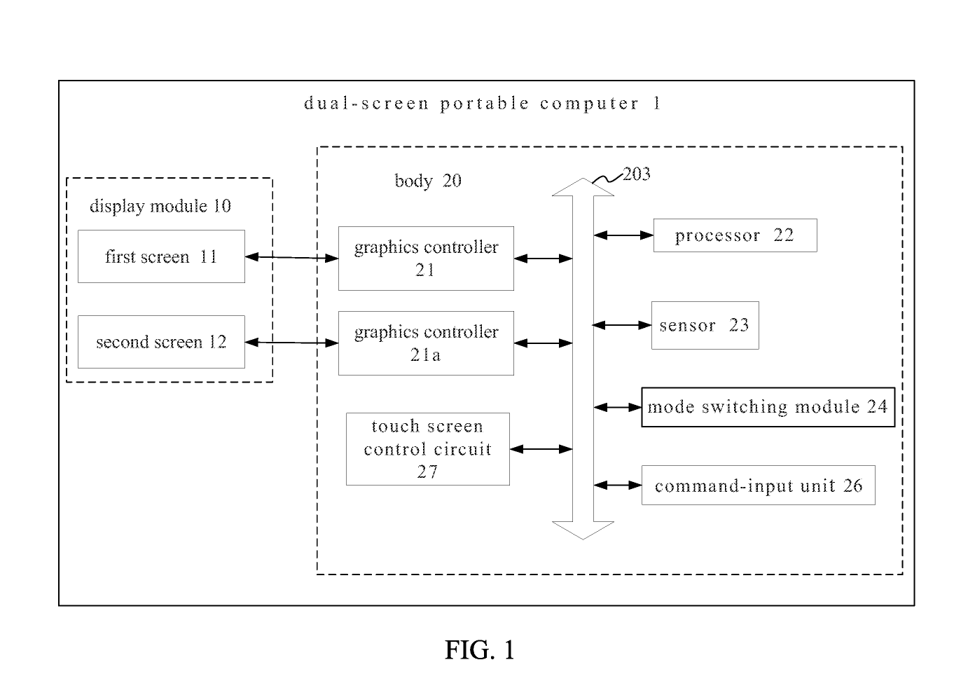

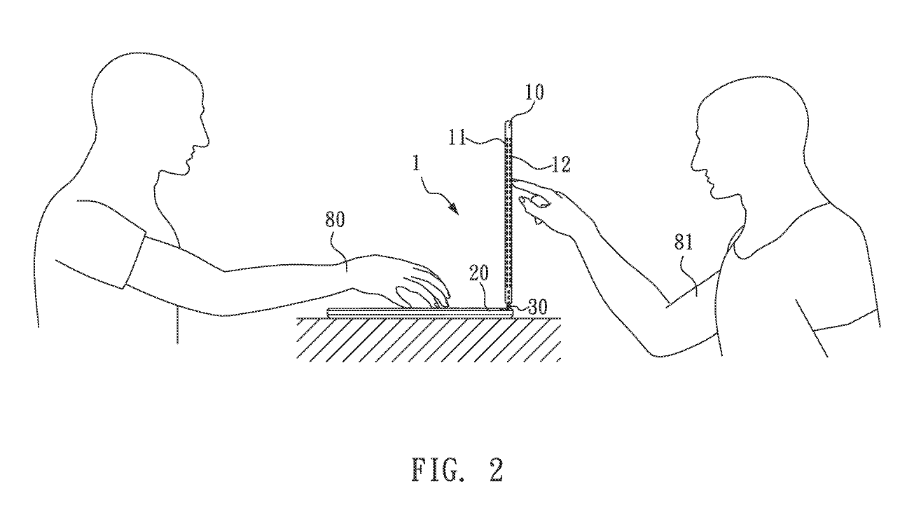

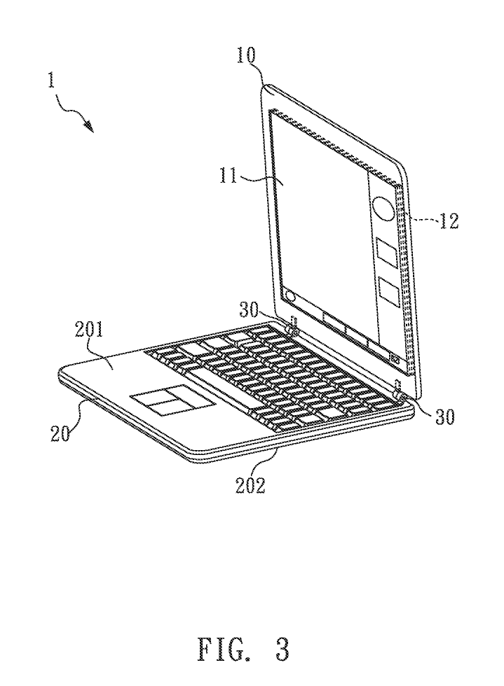

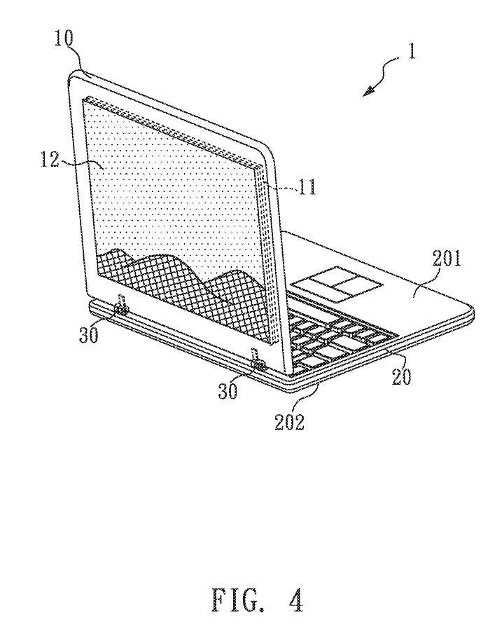

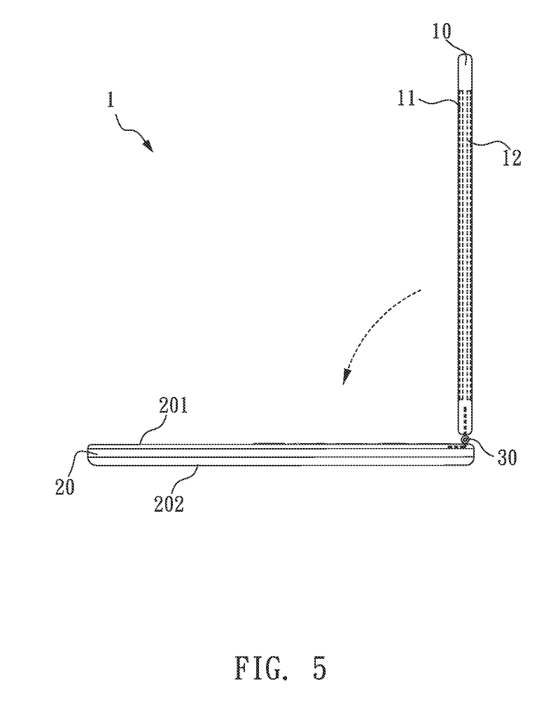

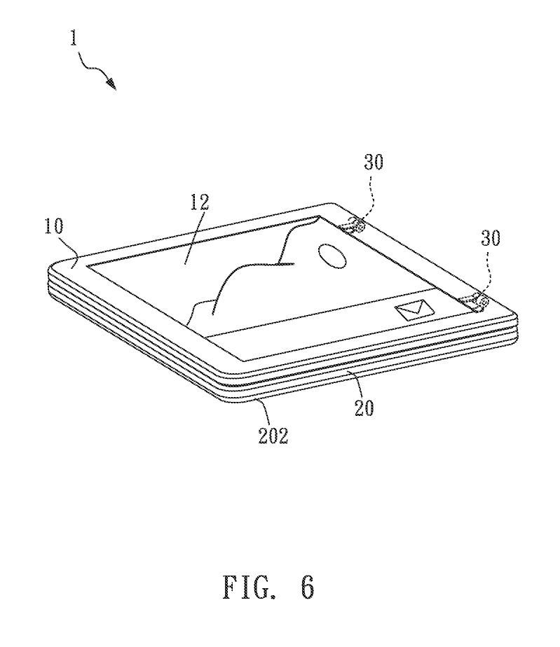

Please refer to FIG. 1˜FIG. 6 regarding the first embodiment of the dual-screen portable computer of the present invention, wherein FIG. 1 illustrates the hardware structure of the first embodiment of the dual-screen portable computer; FIG. 2 is a schematic drawing of the dual-screen portable computer in a laptop mode; FIG. 3 is a schematic drawing of the first embodiment of the dual-screen portable computer in an opened state; FIG. 4 is another schematic drawing of the first embodiment of the dual-screen portable computer in the opened state; FIG. 5 is a lateral view of the first embodiment of the dual-screen portable computer in the opened state; and FIG. 6 is a schematic drawing of the first embodiment of the dual-screen portable computer in a folded state.

As shown in FIG. 1 and FIG. 2, the dual-screen portable computer 1 of the present invention mainly comprises: a display module 10, a body 20, and a rotating device 30. The display module 10 includes a first screen 11 and a second screen 12. The first screen 11 is disposed on one side of the display module 10, and the second screen 12 is disposed on the other side of the display module 10. The body 20 mainly comprises: a plurality of graphics controllers 21, a processor 22, a sensor 23, a mode switching module 24, a command-input unit 26, and a touch screen control circuit 27. The plurality of graphics controllers 21 are electrically connected to the first screen 11 and the second screen 12 individually for controlling the first screen 11 and the second screen 12 to display graphics separately. Therefore, the operating messages or information of the dual-screen portable computer can be displayed separately on the first screen 11 and the second screen 12 of the dual-screen portable computer 1. As shown in FIG. 2 and FIG. 3, graphics can be displayed independently on the first screen 11 and the second screen 12. The processor 22 for implementing operations of the dual-screen portable computer 1 is electrically connected to the plurality of graphics controllers 21 individually. It is noted that although there are two graphics controllers in this embodiment, the graphics controller 21 and the graphics controller 21a, the quantity of the plurality of graphics controllers of the present invention is not restricted to that number. Moreover, in order to increase the applicability of the present invention, the specifications of the graphics controller 21 and the graphics controller 21a can be the same or different. As shown in FIG. 2, because the first screen 11 and the second screen 12 of the dual-screen portable computer 1 are controlled by the graphics controller 21 and the graphics controller 21a separately, information displayed on the first screen 11 and the second screen 12 for user 80 and user 81 to view can be the same or different. In addition, the dual-screen portable computer 1 can be used by user 80 and user 81 individually through a keyboard or a touch screen.

As shown in FIG. 3 and FIG. 4, the first screen 11 is disposed on a side of the display module 10 that is facing the top surface 201 of the body 20, and the second screen 12 is disposed on the opposite side of the display module 10. In this embodiment, the second screen 12 and the first screen 11 are back to back. The rotating device 30 is connected to the display module 10 and the body 20 separately for rotating the display module 10. In this embodiment, the display module 10 is a TFT-LCD, but the present invention is not limited to the abovementioned embodiment. According to development trends of the display module, the display module 10 of the dual-screen portable computer 1 can also be an active display module such as an Active Matrix Organic Light Emitting Diode (AMOLED) display module for displaying images on both sides of a display module.

The rotating device 30 is a single-hinge device in this embodiment. The relative positions of the display module 10 and the body 20 can be changed by rotating the rotating device 30 such that the display module 10 and the body 20 can move closer to each other or farther away from each other. Therefore, the display module 10 and the body 20 can be either in an opened state (FIG. 3˜FIG. 5) or in a folded state (FIG. 6). As shown in FIG. 3˜FIG. 5, the opened state of the dual-screen portable computer 1 of the present invention refers to a state in which the display module 10 is away from both the top surface 201 of the body 20 and the bottom surface 202 of the body 20; i.e., neither the top surface 201 nor the bottom surface 202 of the body 20 is in contact with the display module 10. When the dual-screen portable computer 1 is in the opened state, the usage mode of the dual-screen portable computer 1 is a laptop mode. As shown in FIG. 6, the folded state of the dual-screen portable computer 1 refers to a state in which the display module 10 is close to the top surface 201 of the body 20 or the bottom surface 202 of the body 20; i.e., the display module 10 can be folded to come in contact with either the top surface 201 or the bottom surface 202 of the body 20. When the dual-screen portable computer 1 is in the folded state, the usage mode of the dual-screen portable computer 1 is a tablet mode. It is noted that because the rotating device 30 is a single hinge device, the display module 10 can be rotated only along the direction indicated by the arrow in FIG. 5. Thus, the display module 10 can be folded to the top surface 201 of the body 20, and the second screen 12 is consequently located on the outer surface of the display module 10. As a result, the second screen 12 is the main display screen for the user to operate in the tablet mode in this embodiment. It is noted that in order to implement operations in the tablet mode, the second screen 12 is a touch screen, and the touch screen control circuit 27 of the body 20 is used for transforming the touch contact into electrical signals, all of which are sent to the devices of the body 20 via a system bus 203 for facilitating operations of the dual-screen portable computer 1. It is noted that the present invention is not limited to the abovementioned embodiments; the first screen 11 of the dual-screen portable computer 1 can be a touch screen as well.

In order to switch the dual-screen portable computer 1 between the laptop mode and the tablet mode, the sensor 23 of the body 20 may be used for sensing the relative positions of the display module 10 and the body 20 to determine whether it is in the open or the folded state. A mode switch module 24 for switching operating modes of the dual-screen portable computer 1 based on the relative positions of the display module 10 and the body 20 is electrically connected to the sensor 23. In this embodiment, the sensor 23 is an electromagnetic induction sensor, but the present invention is not limited to that type. The sensor 23 can be a distance sensor, a mechanical switch, or any element capable of sensing whether the display module 10 and the body 20 are folded or opened. Moreover, the mode switch module 24 can be an electronic device with software programs or electrical circuits; the present invention is not limited to the abovementioned embodiments. The function of the sensor 23 and the mode switch module 24 is such that if the display module 10 and the body 20 are in the opened state, the dual-screen portable computer 1 of the present invention enters the laptop mode, and the processor 22 implements operations of the laptop mode, whereas when the display module 10 and the body 20 are in the folded state, the processor 22 implements the tablet mode.

Because the first screen 11 and the second screen 12 of the dual-screen portable computer 1 can display graphics independently, in the laptop mode, both the first screen 11 and the second screen 12 of the dual-screen portable computer 1 can be the main operating display screen for executing the full display feature of the laptop mode. In addition, the dual-screen portable computer 1 has two screens to allow a user 80 to send a screen-activation command to enable a single screen mode or a dual screen mode in the laptop mode. The screen activation command is sent by the command-input unit 26, which is electrically connected to the processor 22. The command-input unit 26 can be a software program or an electrical circuit device with software programs. It is noted that the present invention is not limited to those embodiments, and that the devices within the body 20 communicate via the system bus 203 for implementing the operation of the dual-screen portable computer.

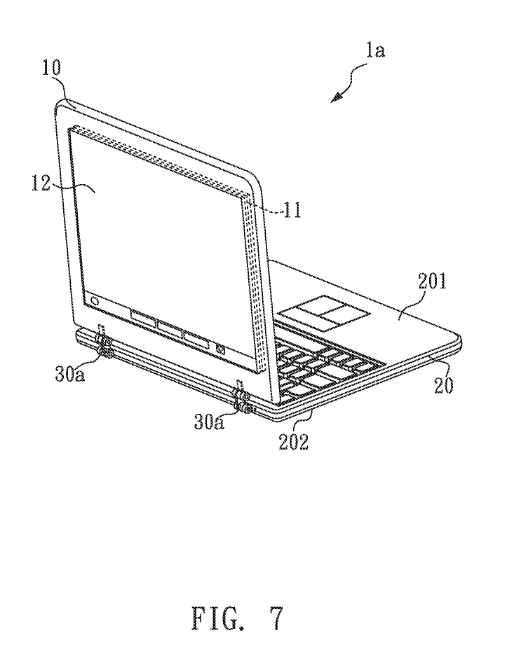

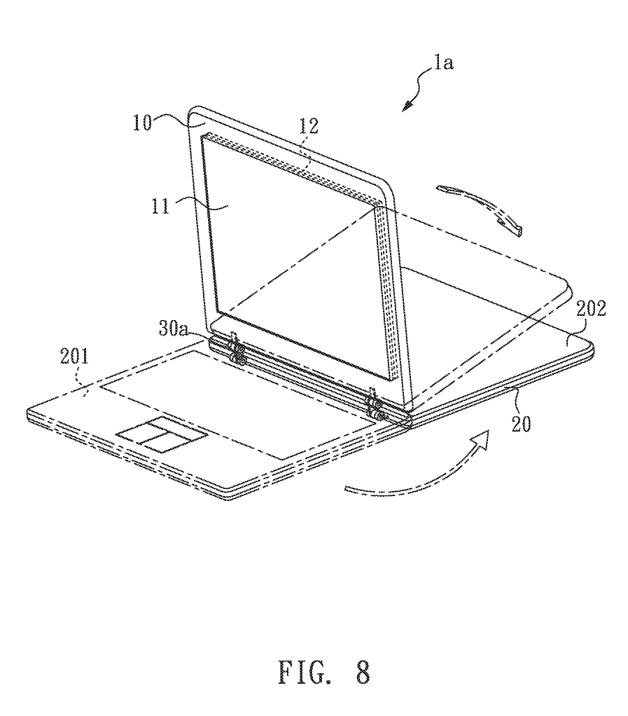

Please refer to FIG. 7 and FIG. 8 regarding the second embodiment of the dual-screen portable computer of the present invention, wherein FIG. 7 is a schematic drawing of the second embodiment of the dual-screen portable computer in the opened state, and FIG. 8 is a schematic drawing illustrating the transition movement of the second embodiment of the dual-screen portable computer from the opened state to the folded state.

In this embodiment, the rotating device 30a is a double-hinge device. As shown in FIG. 8, the rotating device 30a allows the second screen 12 to be folded to the bottom surface 202 of the body 20 or the first screen 11 to be folded to the top surface 201 of the body 20 (please refer to FIG. 6). As a result, the tablet mode of the dual-screen portable computer 1a can be operated in both abovementioned embodiments of the folded state. Therefore, the first screen 11 and the second screen 12 can both implement operations of the tablet mode, and both the first screen 11 and the second screen 12 of the present invention are touch screens in this embodiment.

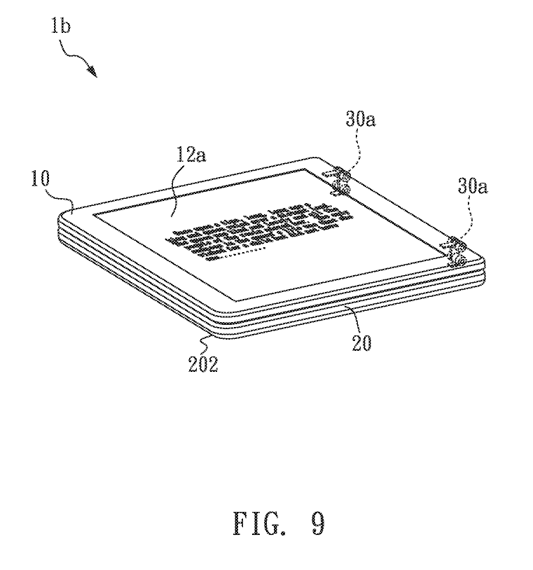

Please refer to FIG. 9. FIG. 9 is a schematic drawing of the third embodiment of the dual-screen portable computer in the folded state. As shown in FIG. 9, the second screen 12a of the present invention is an e-paper display module in this embodiment. If the first screen 11 is folded to the top surface 201 of the body 20, the dual-screen portable computer 1b enters an e-reader mode, and the second screen 12a displays an e-book for reading. Because the e-paper display module is a bi-stable display module, there is no electricity consumption while graphics are displayed, and electricity is consumed only while the graphics change. Therefore, while the e-reader mode is operated, the dual-screen portable computer 1b can be equipped with a processor which has low electricity consumption or low performance, an operating system requiring less memory space, or a low-level graphics controller in order to reduce the consumption of electricity of the dual-screen portable computer 1b. Furthermore, the hardware installed on the dual-screen portable computer 1b can be double processors, double graphics controllers, and double operating systems. Due to the bi-stable feature of the e-paper display module of the second screen 12a, the graphics or words presented on the screen last will still remain on the second screen 12a even when the dual-screen portable computer 1b is switched off. As a result, the bi-stable feature of the second screen 12a can be used as a decorative function for displaying information or graphics chosen by users in order to increase the applicability of the present invention. Because the e-reader mode and the tablet mode can both be operated in the folded state in this embodiment, users can send a mode activation command via the command-input unit 26 to determine which mode is preferred while the dual-screen portable computer 1b is in the folded state. The mode activation command is sent by the command-input unit 26 so that the processor 22 can execute operations of the e-reader mode and the tablet mode. It is here noted that the dual-screen portable computer 1 of the present invention can also be equipped with two processors, two graphics controllers, and two operating systems. The use of the two processors and two operating systems are not limited to the presented embodiment of the dual-screen portable computer 1b.

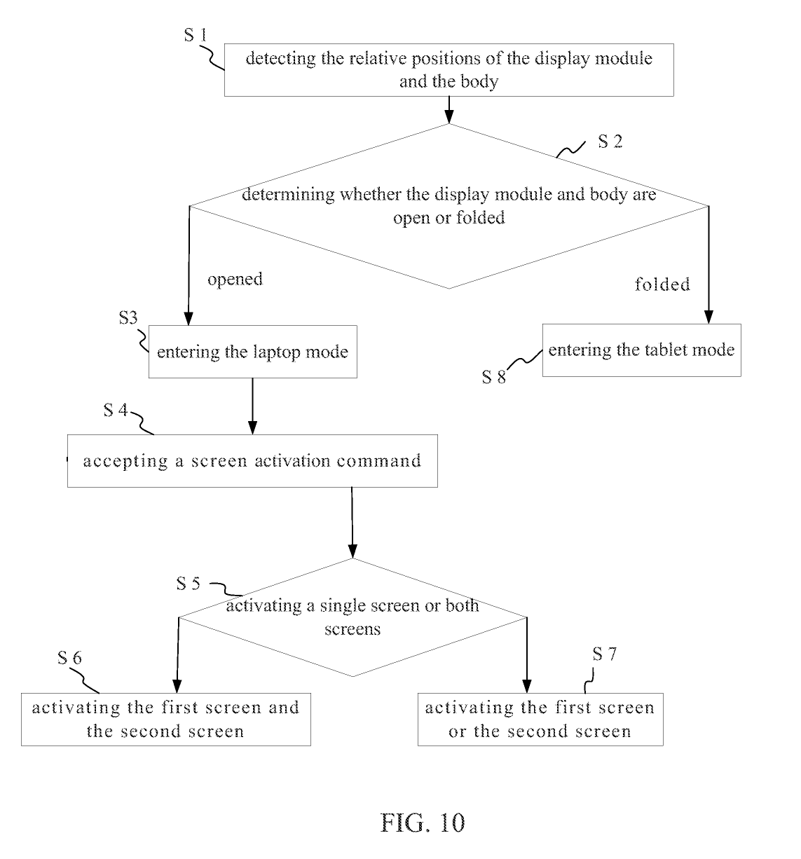

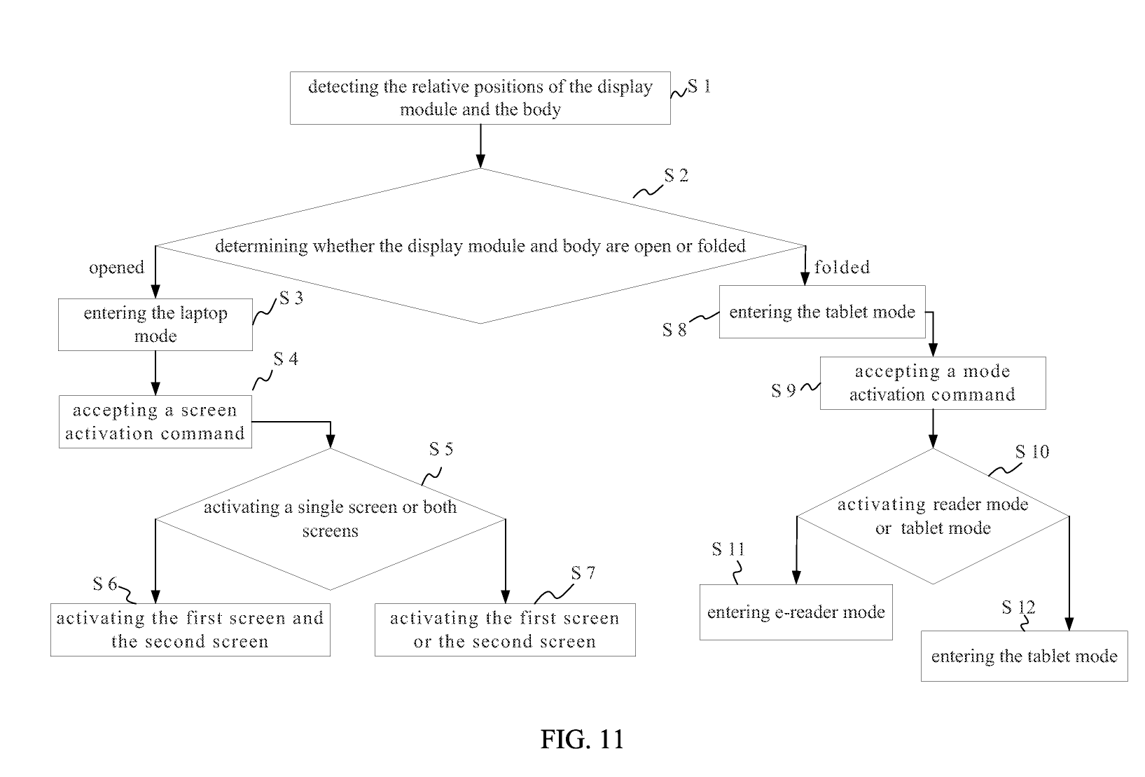

Please refer to FIG. 10 and FIG. 11, wherein FIG. 10 is a flow chart of an embodiment of the switching method of a portable computer of the present invention. FIG. 11 is another flow chart of another embodiment of the switching method of the portable computer of the present invention. The dual-screen portable computer 1 of the present invention is used as an example for illustrating the switching method of the portable computer of the present invention hereinafter. However, the switching method of the portable computer can be applied to various embodiments and is not limited only to the dual-screen portable computer 1. The switching method of the portable computer of the present invention switches the dual-screen portable computer 1 between a laptop mode and a tablet mode, wherein the dual-screen portable computer 1 comprises a display module 10 and a body 20. The display module 10 includes a first screen 11 and a second screen 12. The switching method of the dual-screen portable computer of the present invention comprises the following steps:

Step S1: detecting the relative positions of the display module and the body.

The relative positions of the display module 10 and the body 20 of the dual-screen portable computer 1 can be changed through the rotation of the rotating device 30. Please refer to FIG. 5 and FIG. 6. The dual-screen portable computer 1 of the present invention is in the laptop mode at first. The rotation of the rotating device 30, which is rotated along the direction indicated by the arrow in FIG. 5, allows the display module 10 gradually to move toward the body 20 until the display module 10 is folded to the body 20 (as shown in FIG. 6). The sensor 23 detects the relative positions of the display module 10 and the body 20 and identifies whether the computer is in the opened state or the folded state to switch operating modes.

Step S2: determining whether the display module and body are open or folded.

The operating mode of the dual-screen portable computer 1 is determined by the mode switch module 24, which is electrically connected to the sensor 23, based on the relative positions of the display module 10 and the body 20. If the display module 10 and the body 20 are in the opened state, Step S3 will be implemented. If the display module 10 and the body 20 are in the folded state, Step S8 will be implemented.

Step S3: entering the laptop mode.

If the display module 10 and the body 20 are in the opened state, the dual-screen portable computer 1 enters the laptop mode, which is executed by the processor 22.

Step S4: accepting a screen activation command.

A screen activation command sent by a user via the command-input unit 26 is accepted.

Step S5: activating a single screen or both screens.

If the screen activation command is to activate both screens, Step S6 is implemented.

If the screen activation command is to activate a single screen, Step S7 is implemented.

Step S6: activating the first screen and the second screen.

The first screen 11 and the second screen 12 are activated according to the screen activation command so that both the first screen 11 and the second screen 12 can be operated in the laptop mode at the same time.

Step S7: activating the first screen or the second screen.

The first screen 11 or the second screen 12 is activated according to the screen activation command. Thus either the first screen 11 or the second screen 12 will be operated in the laptop mode.

Step S8: entering the tablet mode.

If the display module 10 and the body 20 are in the folded state, the dual-screen portable computer 1 enters the tablet mode, which is executed by the processor 22.

Step S9: accepting a mode activation command.

A mode activation command is sent by a user via the command-input unit 26 for activating the tablet mode or the e-reader mode.

Step S10: activating the tablet mode or the e-reader mode.

If the mode activation command is to activate the e-reader mode, Step S11 is implemented.

If the screen activation command is to activate the tablet mode, Step S12 is implemented.

Step S11: entering the e-reader mode.

According to the mode activation command, the dual-screen portable computer 1 enters the e-reader mode. When the e-reader mode is being operated, the second screen 12a is the main display screen for e-book operations in this embodiment.

Step S12: entering the tablet mode.

According to the mode activation command, the dual-screen portable computer 1 enters the tablet mode, and the first screen 11 is the main display screen for operating the tablet mode in this embodiment.

It is noted that the switching method of the present invention is not limited to the above-mentioned order. As long as the objects of the present invention can be achieved, the order of the above-mentioned steps can be changed and modified.

Moreover, the above-mentioned embodiments are only for illustration. It is intended that the present invention cover modifications and variations of this invention provided they fall within the scope of the following claims and their equivalents. Therefore, it will be apparent to those skilled in the art that various modifications and variations can be made to the structure of the present invention without departing from the scope or spirit of the invention.

What is claimed is:

1. A dual-screen portable computer comprising:
a display module which comprises:
a first screen disposed on one side of the display module; and
a second screen disposed on the opposite side of the display module; and
a body which comprises:
a plurality of graphics controllers electrically connected to the first screen and the second screen individually for controlling the first screen and the second screen to display graphics separately.

2. The dual-screen portable computer as claimed in claim 1, wherein the dual-screen portable computer further comprises:
a rotating device separately connected to the display module and the body for changing the relative positions of the display module and the body by rotating the display module, thereby allowing the display module to be folded to a top surface of the body or a bottom surface of the body, which is a folded state of the dual-screen portable computer, or the display module is not folded to the body, which is an opened state of the dual-screen portable computer.

3. The dual-screen portable computer as claimed in claim 2, wherein the body further comprises:
a processor electrically connected to the plurality of graphics controllers for implementing operations of the dual-screen portable computer;
a sensor for detecting the relative positions of the display module and the body; and
a mode switching module electrically connected to the sensor for switching the dual-screen portable computer to operate either in a laptop mode or in a tablet mode based on the relative positions;
wherein if the dual-screen portable computer is in the folded state, the processor executes the tablet mode; if the dual-screen portable computer is in the opened state, the processor executes the laptop mode.

4. The dual-screen portable computer as claimed in claim 3, wherein the sensor can be an electromagnetic induction sensor, a distance sensor, or a mechanical switch.

5. The dual-screen portable computer as claimed in claim 4, wherein the body further comprises a command-input unit electrically connected to the processor for sending a mode activation command or a screen activation command.

6. The dual-screen portable computer as claimed in claim 3, wherein the quantity of the plurality of graphics controllers is two, each of which is individually electrically connected to the first screen and the second screen for controlling the first screen and the second screen to display graphics separately.

7. The dual-screen portable computer as claimed in claim 6, wherein the sensor can be an electromagnetic induction sensor, a distance sensor, or a mechanical switch.

8. The dual-screen portable computer as claimed in claim 7, wherein the body further comprises a command-input unit electrically connected to the processor for sending a mode activation command or a screen activation command.

9. The dual-screen portable computer as claimed in claim 6, wherein the second screen is a touch screen; if the dual-screen portable computer is operated in the laptop mode, either the first screen or the second screen can be used for displaying graphics; if the dual-screen portable computer is operated in the tablet mode, the second screen is used for displaying graphics.

10. The dual-screen portable computer as claimed in claim 9, wherein the sensor can be an electromagnetic induction sensor, a distance sensor, or a mechanical switch.

11. The dual-screen portable computer as claimed in claim 9, wherein the first screen and the second screen are both touch screens; while the laptop mode is operated, either the first screen or the second screen can be used for displaying graphics, and while the tablet mode is operated, the second screen is used for displaying graphics.

12. The dual-screen portable computer as claimed in claim 11, wherein the sensor can be an electromagnetic induction sensor, a distance sensor, or a mechanical switch.

13. The dual-screen portable computer as claimed in claim 12, wherein the body further comprises a command-input unit electrically connected to the processor for sending a mode activation command or a screen activation command.

14. The dual-screen portable computer as claimed in claim 2, wherein the rotating device is a double-hinge device; by rotation of the double-hinge device, the first screen can be folded to the top surface of the body, or the second screen can be folded to the bottom surface of the body.

15. The dual-screen portable computer as claimed in claim 14, wherein the sensor can be an electromagnetic induction sensor, a distance sensor, or a mechanical switch.

16. The dual-screen portable computer as claimed in claim 15, wherein the second screen is an e-paper display module; if the first screen is folded to the top surface of the body, the second screen is used for displaying an e-book for reading; if the second screen is folded to the bottom surface of the body, the first screen is used for implementing operations of the dual-screen portable computer.

17. The dual-screen portable computer as claimed in claim 16, wherein the sensor can be an electromagnetic induction sensor, a distance sensor, or a mechanical switch.

18. The dual-screen portable computer as claimed in claim 17, wherein the body further comprises a command-input unit electrically connected to the processor for sending a mode activation command or a screen activation command.

19. A switching method for switching a portable computer selectively to operate in a laptop mode or in a tablet mode, wherein the portable computer comprises a display module and a body, and the switching method comprising the following steps:
detecting the relative positions of the display module and the body of the portable computer to determine whether the display module and the body are in an opened state or a folded state;
if the display module and the body are in the opened state, implement the laptop mode; and
if the display module and the body are in the folded state, implement the tablet mode.

20. The switching method as claimed in claim 19, wherein the display module comprises a first screen and a second screen;
if the portable computer implements the laptop mode, the switching method comprising the following steps:
accepting a screen activation command; and
activating the first screen or the second screen for operating in the laptop mode according to the screen activation command;
if the portable computer implements the tablet mode, the switching method comprising the following steps:
accepting a mode activation command; and
activating the first screen or the second screen for operating the tablet mode according to the mode activation command.

21. The switching method as claimed in claim 20; if the tablet mode is operated, the second screen displays an e-book for reading.
